(19) United States
(12) Patent Application Publication
(10) Pub. No.: US 2025/0224430 A1
(43) Pub. Date: Jul. 10, 2025

(54) COUPLED INDUCTOR CURRENT SENSING

(71) Applicant: Nanowatt Inc., Milpitas, CA (US)

(72) Inventors: Owen Jong, Milpitas, CA (US); Ya Liu, Milpitas, CA (US)

(21) Appl. No.: 18/408,306

(22) Filed: Jan. 9, 2024

(51) Int. Cl. G01R 19/00; G01R 19/165; H02M 1/00

(52) U.S. Cl. CPC G01R 19/0092; G01R 19/16538; H02M 1/0009

(57) ABSTRACT

In accordance with some embodiments of the present disclosure, a current sensing circuit includes a coupled inductor including a first winding and a second winding, a first resistor, a first capacitor including a first side coupled in series with the first resistor, where the first resistor and the first capacitor are coupled in parallel with the first winding, and a second side coupled to the outputs of the first and second windings, a second resistor a second capacitor including a first side coupled in series with the second resistor, where the second resistor and the second capacitor are coupled in parallel with the second winding, and a second side coupled to the outputs of the first and second windings, and a third capacitor including a first side coupled between the first resistor and the first capacitor, and a second side coupled between the second resistor and the second capacitor. A first voltage across the first capacitor is indicative of a first current flowing through the first winding, and a second voltage across the second capacitor is indicative of a second current flowing through the second winding.

### TECHNICAL FIELD

The present disclosure is directed to methods and systems for current sensing in circuits incorporating coupled inductors.

### SUMMARY

In accordance with the present disclosure, circuitry is provided for sensing current in electronic systems including one or more coupled inductors. The circuitry disclosed herein may improve the operational capabilities of systems including coupled inductors, such as for electric power conversion or other suitable applications.

In accordance with some embodiments of the present disclosure, a current sensing circuit includes a coupled inductor including a first winding and a second winding, a first resistor, a first capacitor including a first side coupled in series with the first resistor, where the first resistor and the first capacitor are coupled in parallel with the first winding, and a second side coupled to a second capacitor, a second resistor, the second capacitor including a first side coupled in series with the second resistor, where the second resistor and the second capacitor are coupled in parallel with the second winding, and a second side coupled to the first capacitor, and a third capacitor including a first side coupled between the first resistor and the first capacitor, and a second side coupled between the second resistor and the second capacitor. A first voltage across the first capacitor is indicative of a first current flowing through the first winding, and a second voltage across the second capacitor is indicative of a second current flowing through the second winding.

In some embodiments, the circuit also includes a third resistor coupled in series with the third capacitor, where the third resistor alters a time constant of the coupled inductor.

In some embodiments, the circuit also includes at least one third resistor coupled in parallel with at least one of the first capacitor, the second capacitor, or the third capacitor, where the at least one third resistor scales at least one of the first or second voltages.

In some embodiments, the circuit also includes multiple switches to control current flows through the first and second windings.

In some embodiments, the plurality of switches includes first and second switches coupled in series and third and fourth switches coupled in series, where the first winding is coupled between the first and second switches, and the second winding is coupled between the third and fourth switches.

In some embodiments, outputs of the first and second windings are coupled, and the circuit also includes a third winding, where a first side of the third winding is coupled in series with the coupled outputs of the first and second windings, and a second side of the third winding is coupled between the first and second capacitors.

In some embodiments, outputs of the first and second windings are coupled, and the circuit also includes N−2 windings, where N corresponds to a number of phases of the coupled inductor, and each winding of the N−2 windings corresponds to a respective phase and has an output coupled to the coupled outputs of the first and second windings, N−2 phase resistors, each corresponding to a respective phase, N−2 phase capacitors, each corresponding to a respective phase and including a first side coupled in series with a respective one of the N−2 phase resistors, where each respective one of the N−2 phase resistors and one of the N−2 phase capacitors are coupled in parallel with a corresponding one of the N−2 windings, and a second side coupled to the coupled outputs of the first and second windings and (N−1)!−1 coupling capacitors. Each one of the (N−1)!−1 coupling capacitors includes a first side coupled between a first respective phase resistor and a corresponding first respective phase capacitor, and a second side coupled between a second respective phase resistor and a corresponding second respective phase capacitor.

In accordance with some embodiments of the present disclosure, a current sensing circuit includes a coupled inductor including N windings, where N corresponds to a number of phases of the coupled inductor and the N windings have coupled outputs, N first resistors, N first capacitors, each including a first side coupled in series with a corresponding first resistor, where a respective first resistor and a respective first capacitor are coupled in parallel with a respective one of the N windings, and a second side coupled to the coupled outputs of the N windings, N first amplifiers, where a first input to each first amplifier is coupled between a respective first resistor and a respective first capacitor, and a second input to each first amplifier is coupled to the coupled outputs of the N windings, and a second amplifier, where a first input to the second amplifier is coupled to the coupled outputs of the N windings, and a second input to the second amplifier is coupled to a common node. Each input to each respective winding is coupled in series with a respective one of N second resistors, and each respective one of the N second resistors is further coupled to the common node, and a respective sum of an output voltage of each respective one of the N first amplifiers and an output voltage of the second amplifier is indicative of a respective current flowing through a respective winding of the N windings.

In some embodiments, the circuit also includes N third resistors, where each one of the N third resistors is coupled in parallel with a respective one of the N first capacitors, and each one of the N the third resistor scales the second input to the each one of the first amplifiers.

In some embodiments, the circuit also includes multiple switches to control current flows through the N windings.

In some embodiments, the plurality of switches includes N pairs of first and second switches, each of the first and second switches coupled in series, and each respective winding is coupled between the first and second switches of a respective pair of first and second switches.

In some embodiments, the circuit also includes a third capacitor including a first side coupled to the common node, and a second side coupled to the coupled outputs of the N windings.

In accordance with some embodiments of the present disclosure, a current sensing circuit includes a first coupled inductor including a first input winding and a first output winding, a second coupled inductor including a second input winding and a second output winding, where the first output winding is coupled in series with the second output winding, first and second resistors, a first capacitor including a first side coupled in series with the first resistor and in parallel with the second resistor, and a second side coupled in series with the first input winding, third and fourth resistors, a second capacitor including a first side coupled in series with the third resistor and in parallel with the fourth resistor, and a second side coupled in series with the second input winding, a third inductor coupled in series with the first and second output windings, fifth and sixth resistors coupled in series, and a third capacitor including a first side coupled in between the fifth resistor and the sixth resistor, and a second side coupled in between the second output winding and the third inductor. A difference between a first voltage across the first capacitor and a sense voltage across the third capacitor is indicative of a first current flowing through the first coupled inductor, and a difference between a second voltage across the second capacitor and the sense voltage across the third capacitor is indicative of a second current flowing through the second coupled inductor.

In some embodiments, the circuit also includes multiple switches to control current flows through the first and second windings.

In some embodiments, the plurality of switches includes first and second switches coupled in series and third and fourth switches coupled in series, the first input winding is coupled between the first and second switches, and the second input winding is coupled between the third and fourth switches.

In some embodiments, the circuit also includes N−2 coupled inductors, each including a respective input winding and a respective output winding, where N corresponds to a number of phases of the coupled inductors, and the respective output windings of the N−2 coupled inductors are coupled in series, 2N−4 resistors, where each one of the N−2 coupled inductors is coupled to a corresponding two of the 2N−4 resistors, N−2 capacitors, where each one of the N−2 coupled inductors is coupled to a corresponding one of the N−2 capacitors, each of the N−2 capacitors including a first side coupled in series with a first resistor of the corresponding two of the 2N−4 resistors and in parallel with a second resistor of the corresponding two of the 2N−4 resistors, and a second side coupled in series with a corresponding respective input winding of one of the N−2 coupled inductors. A current flowing through each one of the N−2 coupled inductors is indicated by a difference between a voltage across a corresponding one of the N−2 capacitors and the sense voltage.

In accordance with some embodiments of the present disclosure, a current sensing circuit includes a first coupled inductor including a first input winding and a first output winding, a second coupled inductor including a second input winding and a second output winding, where the first output winding is coupled in series with the second output winding, first and second DrMOS blocks to control current flowing through the first and second coupled inductors, where first outputs of the first and second DrMOS blocks are respectively coupled in series with the first and second input windings, a first capacitor including a first side coupled in series with a second output of the first DrMOS block, and a second side coupled with a first reference voltage, a second capacitor including a first side coupled in series with a second output of the second DrMOS block, and a second side coupled with a second reference voltage, first and second resistors, respective coupled in parallel with the first and second capacitors, a third inductor coupled in series with the first and second output windings, a third resistor and a third capacitor, coupled in series between the first and second outputs of the first DrMOS block, a fourth resistor and a fourth capacitor, coupled in series between the first and second outputs of the second DrMOS block, and a fifth capacitor including a first side coupled in series with a fifth resistor and in parallel with a sixth resistor, and a second side coupled in between the second output winding and the third inductor. A difference between a first voltage across the first capacitor and a voltage across the fifth capacitor is indicative of a first current flowing through the first coupled inductor, and a difference between a second voltage across the second capacitor and the voltage across the fifth capacitor is indicative of a second current flowing through the second coupled inductor.

In some embodiments, the circuit also includes control circuitry to control the first and second DrMOS blocks, where first and second outputs of the control circuitry are respectively coupled to first and second sides of the first capacitor, and third and fourth outputs of the control circuitry are respectively coupled to first and second sides of the second capacitor.

In some embodiments, the circuit also includes a fifth resistor coupled in parallel with the first capacitor, where the fifth resistor scales the first voltage across the first capacitor, and a sixth resistor coupled in parallel with the second capacitor, where the sixth resistor scales the second voltage across the second capacitor.

In some embodiments, the circuit also includes N−2 coupled inductors, where N corresponds to a number of phases of the coupled inductors, each coupled inductor includes an input winding and an output winding, and output windings of the N−2 coupled inductors are coupled in series with the first and second output windings, N−2 DrMOS blocks, each corresponding to a respective phase and configured to control current flowing through a respective one the N−2 coupled inductors, and 2N−4 resistors and 2N−4 capacitors, where two resistors of the 2N−4 resistors and two capacitors of the 2N−4 capacitors correspond to each respective phase, a first of the two resistors and a first of the two capacitors are coupled in parallel between a first output of a corresponding DrMOS block and a corresponding reference voltage, a second of the two resistors and a second of the two capacitors are coupled in series between first and second outputs of the corresponding DrMOS block, where each difference between a voltage across the first of the two capacitors and the voltage across the fifth capacitor is indicative of a respective current flowing through a corresponding coupled inductor.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in some embodiments” appearing herein describe at least one embodiment and implementation, and do not necessarily all refer to the same embodiment. However, they are also not necessarily mutually exclusive.

FIG. 1 shows a two-phase coupled inductor coupled to current-sensing circuitry, in accordance with some embodiments of the present disclosure;

FIG. 2 shows a two-phase coupled inductor coupled to an output winding and current-sensing circuitry, in accordance with some embodiments of the present disclosure;

FIG. 3 shows a three-phase coupled inductor coupled to current-sensing circuitry, in accordance with some embodiments of the present disclosure;

FIG. 4 shows a multi-phase coupled inductor coupled to output amplifiers and current-sensing circuitry, in accordance with some embodiments of the present disclosure;

FIG. 5 shows multiple transformer inductor for voltage regulator (TLVR) circuits and current-sensing circuitry, in accordance with some embodiments of the present disclosure;

FIG. 6 shows a first circuit including multiple TLVR and driver MOSFET (DrMOS) circuits and current-sensing circuitry, in accordance with some embodiments of the present disclosure; and

FIG. 7 shows a second circuit including multiple TLVR DrMOS circuits and current-sensing circuitry, in accordance with some embodiments of the present disclosure;

FIG. 8 shows a third circuit including multiple TLVR and DrMOS circuits and current-sensing circuitry, in accordance with some embodiments of the present disclosure; and

FIG. 9 shows a fourth circuit including multiple TLVR and DrMOS circuits and current-sensing circuitry, in accordance with some embodiments of the present disclosure.

### DETAILED DESCRIPTION

Electronic systems commonly include power conversion systems. Such power conversion systems may increase, decrease, regulate, or otherwise control voltage and/or current levels in the electronic system. With appropriate power conversion techniques, discrete electric components may be integrated while operating at varying power levels, and multiple loads may be powered by a single power supply.

A coupled inductor (e.g., an electronic device including one or more windings that are coupled to a shared magnetic core) may be included as part of a power conversion system. In such systems, the configuration of the coupled inductor may influence the power conversion operations that are available to the system. For example, a ratio of turns between respective windings of a coupled inductor may determine a magnitude of power amplification that occurs between these windings. Coupled inductors may find wide use across various electronic systems due to their high efficiency, small size, and ability to maintain their power conversion performance in high-frequency applications.

During operation of a coupled inductor, current may be controlled to repeatedly flow through respective windings (each of which may correspond to a phase) of the coupled inductor. Based on these controls, there may be a characteristic current waveform that flows through a winding during an operating phase of the coupled inductor, and the current flowing through a first respective phase may be temporally shifted with respect to the current flowing through other respective phases. For example, in an N-phase coupled inductor, where Nis the number of phases, each respective current waveform may be temporally shifted by the length of a duty cycle divided by N (or equivalently, 360° divided by N), where the duty cycle may be equal to the reciprocal of the characteristic current waveform frequency.

While controlling current through a coupled inductor, particularly under high-frequency operation, it may be challenging to continuously and precisely monitor the current flowing through each respective phase. Limits to the precision of this current monitoring may hinder adequate control of the power conversion system and protection of components within and coupled to the power conversion system. Therefore, it is desirable to continuously sense accurate information about the current passing through a coupled inductor.

In accordance with some embodiments of the present disclosure, circuitry is provided for sensing current through coupled inductors. The sensing circuitry includes one or more resistor-capacitor (RC) network that is coupled in parallel with a winding through which the current is to be sensed. Various sensing circuits may be implemented by incorporating this fundamental structure with additional electrical devices that support the power conversion and/or sensing operations. For a given sensing circuit, signals at specific nodes of the circuit are provided as being indicative of the current flowing through a respective winding. In some embodiments, voltages are directly sensed at specific nodes of the circuit, and current flowing through the respective windings may be determined based on the sensed voltages. For example, a current flowing through a respective winding may be equal to a voltage (e.g., that is sensed and indicative of the current) divided by a known resistance (e.g., the resistance of the respective winding). The magnitude of such current flow may be configured by a gain resistance, as may be configured by resistors, amplifiers, capacitors, and/or other elements of the circuit (e.g., by adding, removing, reconfiguring, or resizing the aforementioned elements).

The sensing circuitry provided herein may operate on two-phase or multi-phase (e.g., three or more phases) coupled inductor systems. In some embodiments, switching circuitry is provided to control the current flowing through a respective winding. In some embodiments, resistors and/or amplifiers (e.g., op-amps or other suitable amplifiers) are provided to scale voltage signals (e.g., by tuning a gain resistance) in support of current sensing. In some embodiments, the coupled inductor system includes transformer inductor for voltage regulator (TLVR) circuitry or TLVR and driver MOSFET (DrMOS) circuitry.

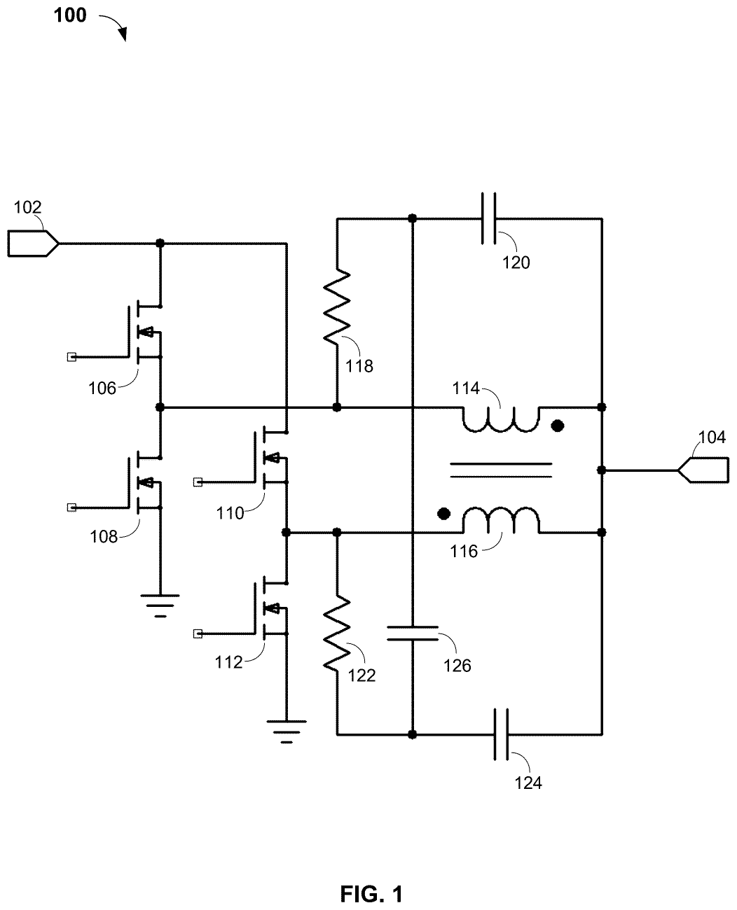

FIG. 1 shows a circuit 100 including a two-phase coupled inductor coupled to current-sensing circuitry, in accordance with some embodiments of the present disclosure. Circuit 100 includes input 102 and output 104, as well as windings 114 and 116. Outputs of windings 114 and 116 are coupled to each other and to output 104. Circuit 100 includes switches 106 and 108, which may control a current flowing through winding 114, as well as switches 110 and 112, which may control a current flowing through winding 116. Windings 114 and 116 are coupled (e.g., via a shared magnetic core) and thus cumulatively represent the two-phase coupled inductor of circuit 100. A first series RC path is coupled in parallel with winding 114 and includes resistor 118 and capacitor 120. A second series RC path is coupled in parallel with winding 116 and includes resistor 122 and capacitor 124. Circuit 100 also includes capacitor 126 (e.g., a coupling capacitor), which includes a first side coupled between resistor 118 and capacitor 120 and a second side coupled between resistor 122 and capacitor 124. In some embodiments, capacitor 126 may influence a transient property (e.g., a time constant) of circuit 100. For example, capacitor 126 may influence the sensing response speed of capacitors 120 and 124, or it may influence the coupling between windings 114 and 116.

In some embodiments, operation of circuit 100 includes repeated toggling of at least switches 106 and 110. When switch 106 is ON, controlled current may flow through winding 114, and when switch 110 is ON, controlled current may flow through winding 116. In some embodiments, switches 106 and 110 are controlled such that neither switch is ON at the same time (e.g., when switch 106 turns OFF, switch 110 turns ON, and vice versa). It will be understood that based on the inductive properties of windings 114 and 116, as well as the coupled nature of these windings, the windings may still conduct current even when the respective current control switch is OFF. Thus, after an initial startup period, switch 106 may be turned ON to increase a current flowing through winding 114, and it may subsequently be turned OFF to reduce (but not bring to zero) the current flowing through winding 114; the same may be true with respect to switch 110 and winding 116. In some embodiments, a single phase of operation may include turning a switch ON to increase the current flowing through a winding until it reaches a maximum value, and then turning that switch OFF to reduce the current flowing through the winding until it reaches a minimum value.

During operation of circuit 100, the phase currents flowing through windings 114 and 116 may be respectively sensed based on the voltage sensed across capacitors 120 and 124. Based on the properties of the first and second series RC paths, as well as the capacitor 126, the voltage sensed across capacitors 120 and 124 may indicate the current flowing through windings 114 and 116. For example, the phase current flowing through winding 114 multiplied by the series resistance of winding 114 may be equal to the voltage across capacitor 120. In some embodiments, a gain (e.g., amplification or reduction) of the phase current through winding 114 may be configured by resistor 118 and/or other resistive elements in circuit 100. Likewise, the phase current flowing through winding 116 multiplied by the series resistance of winding 116 may be equal to the voltage across capacitor 124. In some embodiments, a gain of the phase current through winding 116 may be configured by resistor 122 and/or other resistive elements in circuit 100. In some embodiments, these phase currents may be sensed with a fast response time. For example, the sensed voltages may accurately sense current flowing through the windings of circuit 100 during operation at switching frequencies (e.g., of switches 106 and 110) of 200 kHz or higher. Based on accurate sensing of the currents flowing through windings 114 and 116, circuit 100 may be operated precisely at high speeds and without risk of damaging the elements shown in circuit 100 or other elements connected thereto.

In some embodiments, additional resistors may be included in circuit 100. In particular, an additional resistor may be coupled in parallel with any one or more of capacitors 120, 124, or 126. These additional resistors may scale (e.g., increase or reduce) the magnitude of the sensed voltage signals or may influence a transient property (e.g., a time constant) of the sensed voltage signals. For example, a resistor in parallel with capacitor 120 may scale the voltage signal that may be sensed across capacitor 120 and a resistor in parallel with capacitor 124 may scale the voltage signal that may be sensed across capacitor 124. A resistor in parallel with capacitor 126 may influence a time constant or other transient property of circuit 100.

In some embodiments, switches 106, 108, 110, and 112 may be MOSFETs (e.g., n-type MOSFETs), as shown in circuit 100. It will be understood that other switch devices (e.g., using p-type MOSFETs, any other suitable switching device, or any combination thereof) or switch configurations (e.g., with different coupling paths to windings 114 and 116) may similarly operate circuit 100 and related embodiments thereof. During operation of circuit 100, switches 106, 108, 110, and 112 may be toggled with a specific switching frequency and phase shift (i.e., temporal offset) such that controlled current, including desired current maxima and minima, may flow through windings 114 and 116. In some embodiments, the pair of switches 106 and 108 may operate such that switch 108 turns ON after switch 106 turns OFF; the pair of switches 110 and 112 may be operated similarly. In some embodiments, the pair of switches 110 and 112 may be operated to turn ON and OFF after the pair of switches 106 and 108 have been operated to turn ON and OFF. For example, a single duty cycle of circuit 100 may include sequentially toggling each of switches 106, 108, 110, and 112. It will be understood that these switching schemes are merely illustrative, and the switches may be operated in any desired fashion without departing from the teachings of the present disclosure.

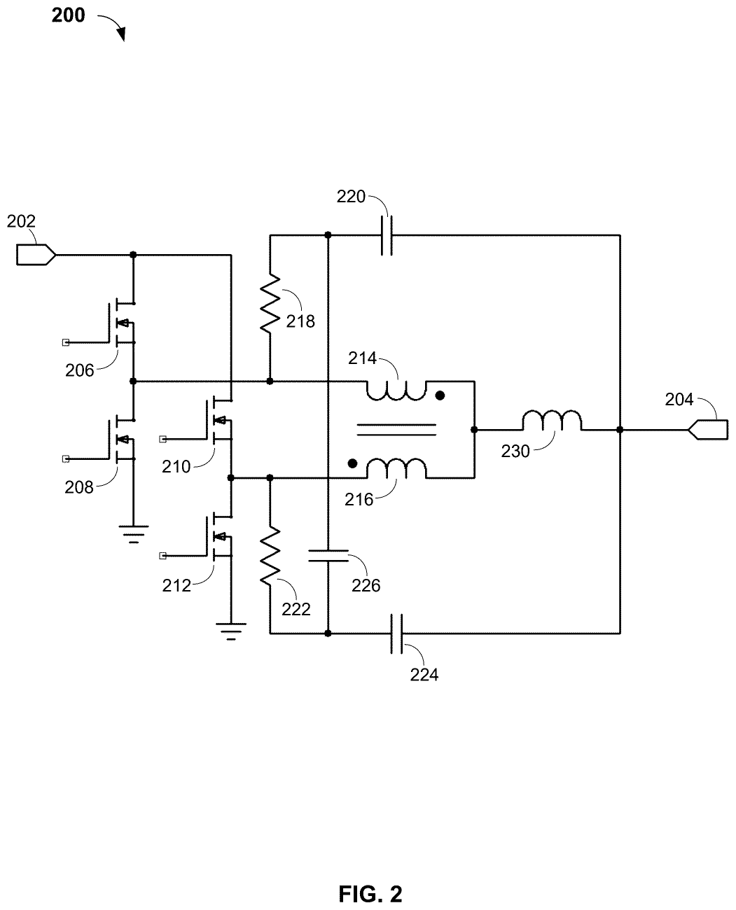

FIG. 2 shows circuit 200 including a two-phase coupled inductor coupled to an output winding and current-sensing circuitry, in accordance with some embodiments of the present disclosure. In circuit 200, elements 202, 204, 206, 208, 210, 212, 214, 216, 218, 220, 222, 224, and 226 may, in some embodiments, respectively correspond to elements 102, 104, 106, 108, 110, 112, 114, 116, 118, 120, 122, 124, and 126. Compared to circuit 100, circuit 200 includes an additional winding 230. The input to winding 230 is coupled to the coupled outputs of windings 214 and 216, and the output of winding 230 is coupled to the output 204 of circuit 200. Phase currents may be sensed in circuit 200 following the procedure described above for sensing phase currents in circuit 100 (e.g., based on the corresponding elements).

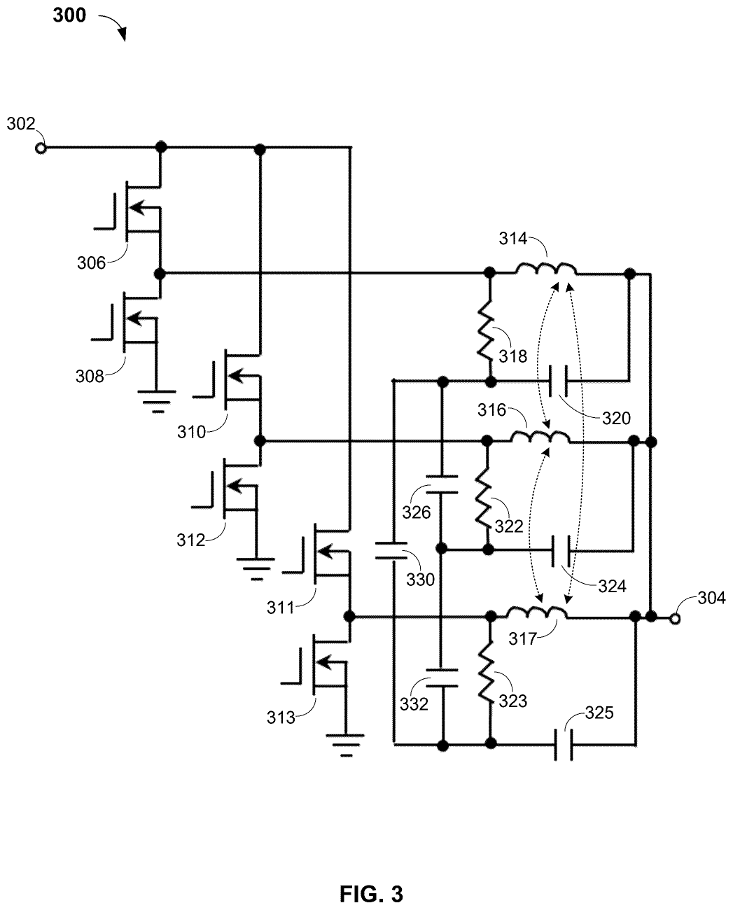

FIG. 3 shows circuit 300 including a three-phase coupled inductor coupled to current-sensing circuitry, in accordance with some embodiments of the present disclosure. In circuit 300, elements 302, 304, 306, 308, 310, 312, 314, 316, 318, 320, 322, 324, and 326 may, in some embodiments, respectively correspond to elements 102, 104, 106, 108, 110, 112, 114, 116, 118, 120, 122, 124, and 126. Compared to circuit 100, circuit 300 includes an additional pair of switches 311 and 313, an additional winding 317, an additional series RC path coupled in parallel with winding 317, where the additional RC path includes resistor 323 and capacitor 325, and additional capacitors 330 and 332. As shown by the dashed curves and arrows, windings 314, 316, and 317 are coupled (e.g., via a shared magnetic core) to realize the three-phase coupled inductor. It will be understood that while three phases are shown in circuit 300, these teachings will be extendable to a multi-phase circuit with any number of three or more coupled inductors or phases. As elements 311, 313, 317, 323, 325, 330, and 332 were added to two-phase circuit 100 to realize three-phase circuit 300, similar elements may be added to circuit 300 to realize circuits of four or more phases using the teachings herein.

During operation of circuit 300, voltages sensed across capacitors 320, 324, and 325 may be respectively indicative of phase currents flowing through windings 314, 316, and 317. For example, each of those respective phase currents multiplied by the respective series winding resistance may be equal to the respective voltages across each of those respective capacitors. In some embodiments, the gains of those phase currents may be configurable based on the sizing of the resistors coupled to the windings (e.g., resistors 318, 322, or 323, respectively, and/or other resistive elements in circuit 300).

In view of the above-mentioned operation of the first pair of switches 106 and 108 (e.g., as corresponding to switches 306 and 308) and the second pair of switches 110 and 112 (e.g., as corresponding to switches 310 and 312), third pair of switches 311 and 313 may be operated similarly. For example, in a given duty cycle, the first, second, and third pairs of switches in circuit 300 may be toggled sequentially, and during operation of the third pairs of switches, switch 311 may be turned OFF before switch 313 is turned ON. Thus, amplitude- and phase-controlled current may be driven through windings 314, 316, and 317.

Capacitor 330 couples the RC path including resistor 318 and capacitor 320 to the RC path including resistor 323 and capacitor 325. Capacitor 332 couples the RC path including resistor 322 and capacitor 324 to the RC path including resistor 323 and capacitor 325. In circuit 300, the connections of capacitors 326, 330, and 332 result in every respective RC path that is coupled in parallel to a respective winding being coupled to every other RC path that is coupled in parallel to a winding. For the three-phase coupled inductor (N=3), three capacitors, or equivalently (N−1)! capacitors, are implemented to realize coupling between every combination of two respective RC paths that are coupled in parallel to a winding of the coupled inductor. For any multi-phase circuit extended from circuit 300, (N−1)! capacitors (e.g., coupling capacitors) may be included, in addition to at least the capacitors of the respective RC paths. These (N−1)! capacitors may be arranged such that each RC path coupled in parallel to a winding of the N-phase coupled inductor is directly coupled to each other RC path coupled in parallel to a winding of the N-phase coupled inductor.

In some embodiments, additional resistors may be included in circuit 300. In particular, an additional resistor may be coupled in parallel with any one or more of capacitors 320, 324, 325, 326, 330, or 332. These additional resistors may scale (e.g., increase or reduce) the magnitude of the sensed voltage signals or may influence a transient property (e.g., a time constant) of the sensed voltage signals. For example, a resistor in parallel with any one or more of capacitors 320, 324, or 325 may scale the voltage signal that may be sensed across those capacitors. For example, a resistor in parallel with any one or more of capacitors 326, 330 or 332 may influence a time constant or other transient property of circuit 300.

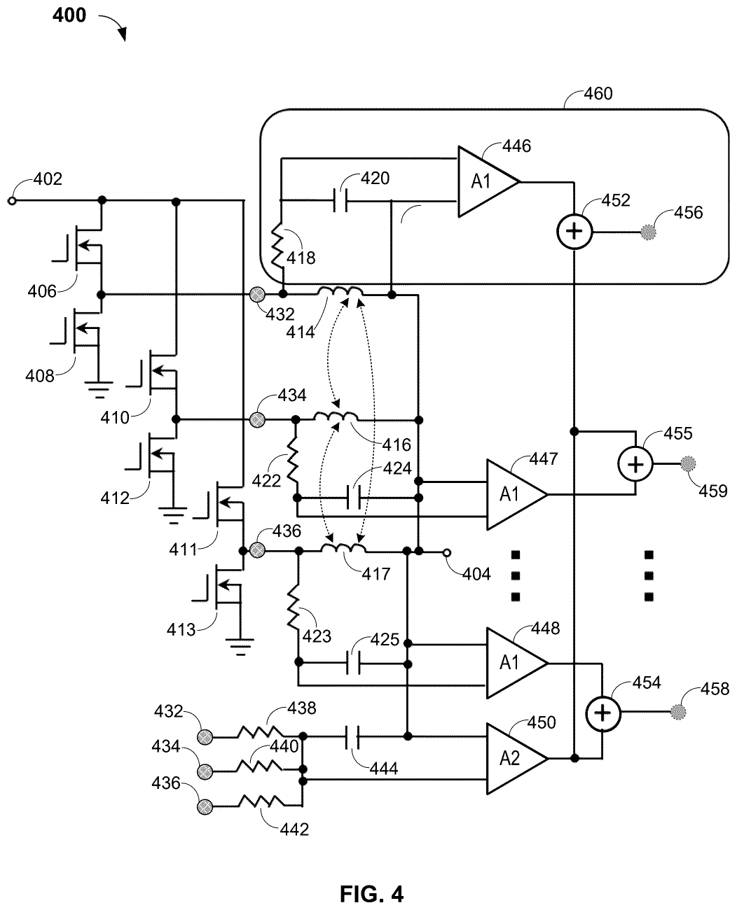

FIG. 4 shows circuit 400 including a multi-phase coupled inductor coupled to output amplifiers and current-sensing circuitry, in accordance with some embodiments of the present disclosure. In circuit 400, elements 402, 404, 406, 408, 410, 411, 412, 413, 414, 416, 417, 418, 420, 422, 423, 424, and 425 may, in some embodiments, respectively correspond to elements 302, 304, 306, 308, 310, 311, 312, 313, 314, 316, 317, 318, 320, 322, 323, 324, and 325. As shown by the dashed curves and arrows, windings 414, 416, and 417 are coupled (e.g., via a shared magnetic core) to realize the three-phase coupled inductor. Compared to circuit 300, circuit 400 additionally includes a series of amplifiers with gain A1, including amplifiers 446, 447, and 448, each of which corresponds to a respective phase. Circuit 400 also additionally includes amplifier 450 with gain A2, resistors 438, 440, and 442, capacitor 444, and voltage adders 452 and 454. Circuit 400 may be extended to more than three phases, as indicated by the “ . . . ”, where each additional phase may include an additional winding that is coupled to a reiteration of the cumulative circuit elements shown in block 460.

In FIG. 4 and elsewhere, the gray circles enclosed by sold lines and filled with white diagonal cross-hatching represent nodes that are coupled to each other, despite the wires not being shown as physically touching (for purposes of brevity and clarity in the figures). In FIG. 4 and elsewhere, the gray circles enclosed by dotted lines represent nodes of reference. It will be understood that when voltages are sensed at these nodes of reference, the voltages are sensed with respect to a common voltage (e.g., ground or any other suitable reference voltage).

Thus, circuit nodes 432, 434, and 436 respectively couple windings 414, 416, and 417 in parallel with resistors 438, 440, and 442. Across those resistors is a pair of parallel paths respectively including couplings to capacitor 444 and the first input of amplifier 450. The other side of capacitor 444 is coupled to the outputs of windings 414, 416, and 417 (which are coupled) as well as the second input of amplifier 450 (which is coupled to the outputs of the windings). The node at the second input of amplifier 450 is similarly coupled to the first inputs of each amplifier 446, 447, and 448. The second input of each amplifier amp 446, 447, and 448 is coupled between the resistor and the capacitor of the respective RC path that is coupled in parallel to the winding with a phase corresponding to that of the respective amplifier amp 446, 447, or 448.

During operation of circuit 400, current may be sensed through the winding of each phase based on the output provided by the phase-corresponding voltage adder. For example, the phase current through winding 414 may be indicated by the output of voltage adder 452 at node 456, the phase current through winding 416 may be indicated by the output of voltage adder 455 at node 459, and the phase current through winding 417 may be indicated by the output of voltage adder 454 at node 458. For example, each of those respective phase currents multiplied by the respective series winding resistance may be equal to the respective voltages at the outputs of each of those respective adders. In some embodiments, the gains of those phase currents may be configurable based on the properties of those amplifiers (e.g., based on the configurable gain A1 of amplifiers 446, 447, or 448, respectively) and/or the sizes of the resistors coupled to the windings (e.g., resistors 418, 422, or 423, respectively, and/or resistive elements in circuit 400). Moreover, modifying one or both of gains A1 and A2 may scale the voltage that may be sensed at the outputs of each of these voltage adders.

Output 404 of circuit 400 may be coupled in parallel with (i) each winding 414, 416, and 417, (ii) the first input of each amplifier 446, 447, and 448, and (iii) the second input of amplifier 450. In some embodiments, a load may be coupled to output 404.

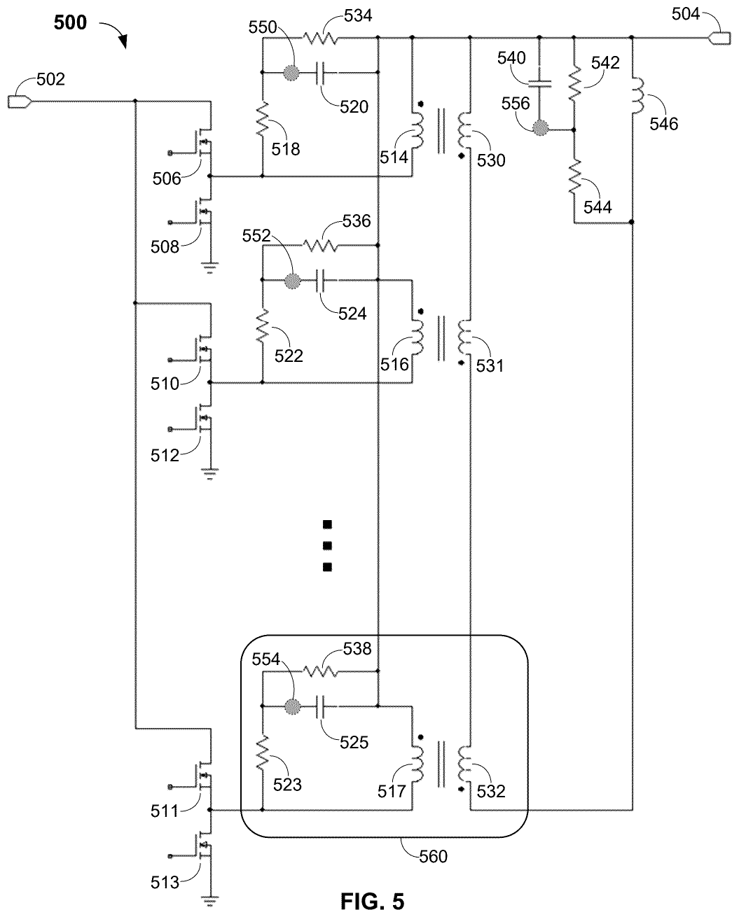

FIG. 5 shows circuit 500 including multiple coupled inductors coupled to transformer inductor for voltage regulator (TLVR) circuitry and current-sensing circuitry, in accordance with some embodiments of the present disclosure. In circuit 500, elements 502, 504, 506, 508, 510, 511, 512, 513, 514, 516, 517, 518, 520, 522, 523, 524, and 525 may, in some embodiments, respectively correspond to elements 402, 404, 406, 408, 410, 411, 412, 413, 414, 416, 417, 418, 420, 422, 423, 424, and 425. Rather than including a single winding for each phase (e.g., as in circuits 100, 200, 300, and 400), circuit 500 includes a respective coupled inductor for each phase, where each coupled inductor includes a pair of coupled input and output windings. In particular, circuit 500 includes at least input windings 514, 516, and 517, each of which is respectively coupled to output windings 530, 531, and 532 (e.g., via a respective magnetic core). The input windings 514, 516, and 517 are coupled in parallel, and the output windings 530, 531, and 532 are coupled in series. Circuit 500 also includes winding 546, which is coupled between output 504 and output winding 532. Winding 546 is coupled in parallel with the path of windings 530, 531, and 532. Winding 546 is also coupled in parallel with a path including resistor 544 coupled in series with the parallel RC combination including capacitor 540 and resistor 542. Circuit 500 may be extended to more than three phases, as indicated by the “ . . . ”, where each additional phase may include a reiteration of the cumulative circuit elements shown in block 560 and the corresponding couplings.

During operation of circuit 500, current may be sensed through each respective coupled inductor based on at least the voltages at nodes 550, 552, 554, and 556. For example, the phase current through winding 514 may be indicated by the difference between the voltage at node 550 and the voltage at node 556; the phase current through winding 516 may be indicated by the difference between the voltage at node 552 and the voltage at node 556; and the phase current through winding 517 may be indicated by the difference between the voltage at node 554 and the voltage at node 556. For example, each of those respective phase currents multiplied by the respective resistance series winding may be equal to each of those respective voltage differences. In some embodiments, the gains of those phase currents may be configurable based on the sizing of resistors coupled to the windings (e.g., resistors 518 and 534, resistors 522 and 536, or resistors 523 and 538, respectively, and/or other resistive elements in circuit 500).

Output 504 of circuit 500 may be coupled in parallel with (i) each input winding 514, 516, and 517, (ii) the series path of output windings 530, 531, and 532, (iii) the winding 546, and (iv) the RC path coupled in parallel with winding 546. In some embodiments, a load may be coupled to output 504.

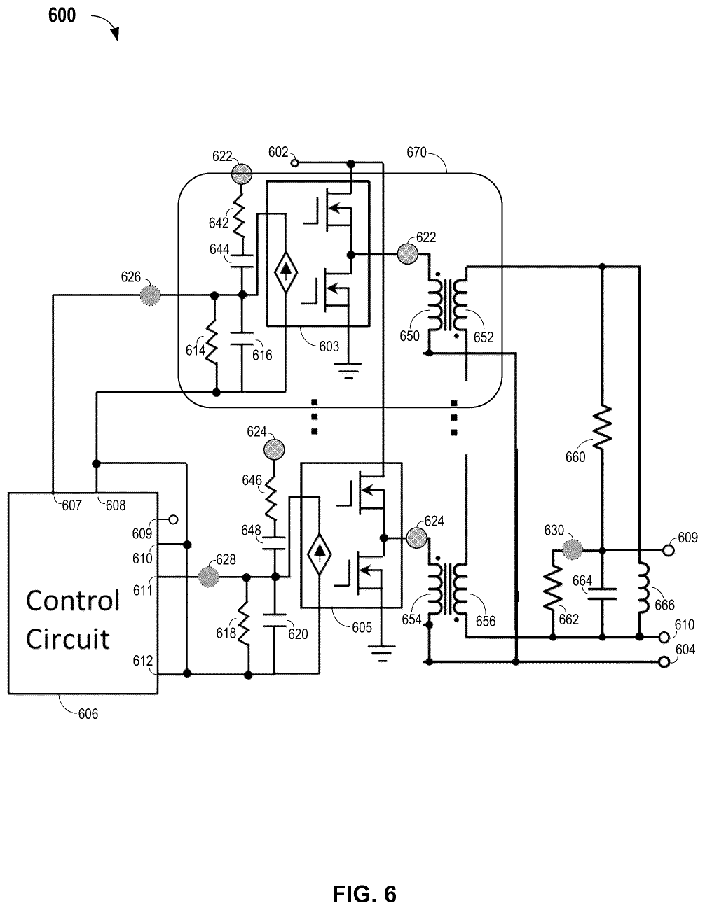

FIG. 6 shows circuit 600 including multiple coupled inductors coupled to TLVR and driver MOSFET (DrMOS) circuitry, in accordance with some embodiments of the present disclosure. In circuit 600, elements 602, 604, 642, 644, 646, 648, 650, 652, 654, 656, 660, 662, 664, and 666, may, in some embodiments, respectively correspond to elements 502, 504, 518, 520, 523, 525, 514, 530, 517, 532, 544, 542, 540, and 546. Compared to circuit 500, circuit 600 additionally include DrMOS blocks 603 and 605, control circuit block 606 (including connection pins 607-612 therein), a first parallel RC path including resistor 614 and capacitor 616 and a second parallel RC path including resistor 618 and capacitor 620, where each parallel RC path is coupled between an input and an output of the respective DrMOS blocks 603 and 605.

Each DrMOS block 603 and 605 includes a respective current source. DrMOS block 603 drives current through input winding 650 (which couples to output winding 652, e.g., via a shared magnetic core) and DrMOS block 605 drives current through input winding 654 (which couples to output winding 656, e.g., via a shared magnetic core). Voltage input 602 may be an input to each DrMOS block 603 and 605, through which an input signal may be coupled to input windings 650 and 654. Nodes 626 and 628 may be signals respectively driven by first outputs of DrMOS blocks 603 and 605 and provided to control circuit block 606. Nodes 622 and 624 may be signals respectively driven by second outputs of DrMOS blocks 603 and 605. Nodes 622 and 626 are coupled to opposite sides of the series RC path including resistor 642 and capacitor 644. Nodes 624 and 628 are coupled to opposite sides of the series RC path including resistor 646 and capacitor 648. Nodes 622 and 624 are also respectively coupled to input windings 650 and 654. Node 626 also is coupled to the parallel RC path including resistor 614 and capacitor 616, the other sides of which couple to a reference voltage (e.g., ground or any other suitable reference voltage level) that is shared across the control circuit block 606 and both DrMOS blocks 603 and 605. For example, the reference voltage may be coupled to control circuit block 606 via pin 610. Node 628 is coupled to the parallel RC path including resistor 618 and capacitor 620, the other sides of which also couple to the shared reference voltage. The shared reference voltage may also be coupled (e.g., through pin 610) to an end of the series path including at least output windings 650 and 654.

During operation of circuit 600, phase current may be sensed through each respective coupled inductor based on the voltages at nodes 626, 628, and 630. For example, the phase current through winding 650 may be indicated by the difference between the voltage at node 626 and the voltage at node 630; the phase current through winding 654 may be indicated by the difference between the voltage at node 628 and the voltage at node 630. For example, each of those respective phase currents multiplied by the respective series winding resistance may be equal to each of those respective voltage differences. In some embodiments, the gains of those phase currents may be configurable based on the sizing of resistors coupled to the windings (e.g., resistors 642 and 614 and resistors 646 and 618, respectively, and/or other resistive elements in circuit 500). Node 630 may also be connected to control circuit block 606 (e.g., through pin 609) to realize control of DrMOS blocks 603 and 605 based on the sensed currents.

Output 604 of circuit 600 may be coupled in series with at least the input windings 650 and 654. In some embodiments, a load may be coupled to output 604.

Circuit 600 may be extended to three or more phases, as indicated by the “ . . . ”, where each additional phase may include a reiteration of the cumulative circuit elements shown in block 670 and the corresponding couplings. Inclusion of such additional phases may also include additional connections to control circuit block 606 (e.g., additional iterations of pins 611 and 612, which respectively correspond to positive and negative connections from an N-phase circuit block to a control circuit).

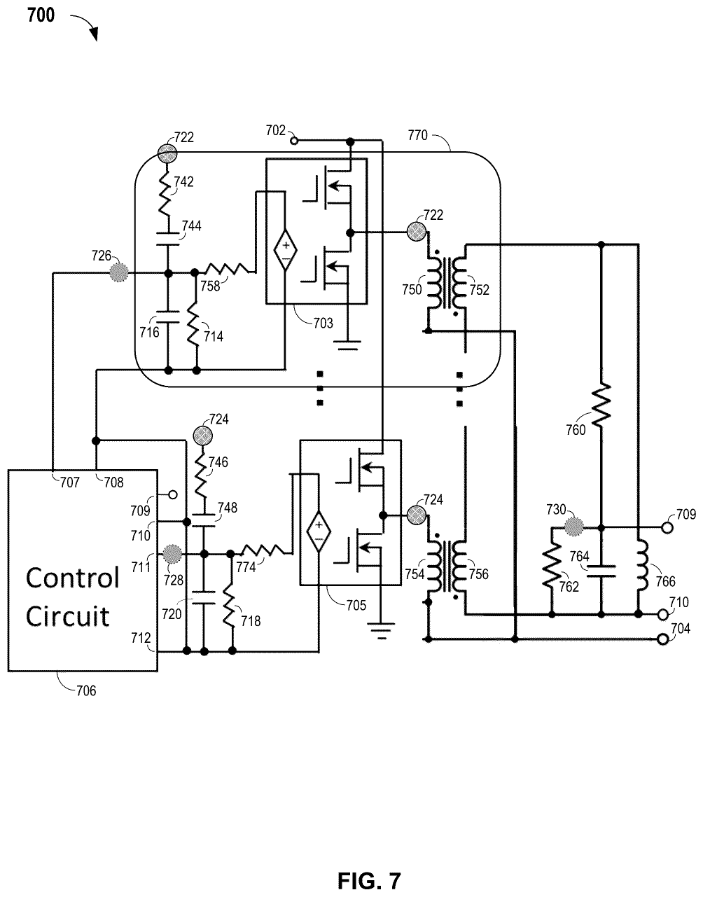

FIG. 7 shows circuit 700 including multiple coupled inductors coupled to TLVR and DrMOS circuitry, in accordance with some embodiments of the present disclosure. In circuit 700, elements 702, 704, 706, 707, 708, 709, 710, 711, 712, 714, 716, 718, 720, 722, 724, 726, 728, 730, 742, 744, 746, 748, 750, 752, 754, 756, 760, 762, 764, and 766 may, in some embodiments, respectively correspond to elements 602, 604, 606, 607, 608, 609, 610, 611, 612, 614, 616, 618, 620, 622, 624, 626, 628, 630, 642, 644, 646, 648, 650, 652, 654, 656, 660, 662, 664, and 666. Compared to circuit 600, circuit 700 exchanges DrMOS blocks 603 and 605 for DrMOS blocks 703 and 705, each of which includes a respective voltage source, and it exchanges control circuit block 606 with control circuit block 706. Circuit 700 additionally includes resistors 758 and 778, the resistances of which respectively determine the currents provided by the voltage sources of DrMOS blocks 703 and 705. In some embodiments, circuit 700 may not include resistor 714 and/or 718.

During operation of circuit 700, current may be sensed through each respective coupled inductor based on the abovementioned procedure for current sensing in circuit 600 (e.g., based on the corresponding elements therein).

Output 704 of circuit 700 may be coupled in series with at least the input windings 750 and 754. In some embodiments, a load may be coupled to output 704.

Circuit 700 may be extended to more than three phases, as indicated by the “· ·-” where each additional phase may include a reiteration of the cumulative circuit elements shown in block 770 and the corresponding couplings. Inclusion of such additional phases may also include additional connections to control circuit block 706 (e.g., additional iterations of pins 711 and 712, which respectively correspond to positive and negative connections from an N-phase circuit block to a control circuit).

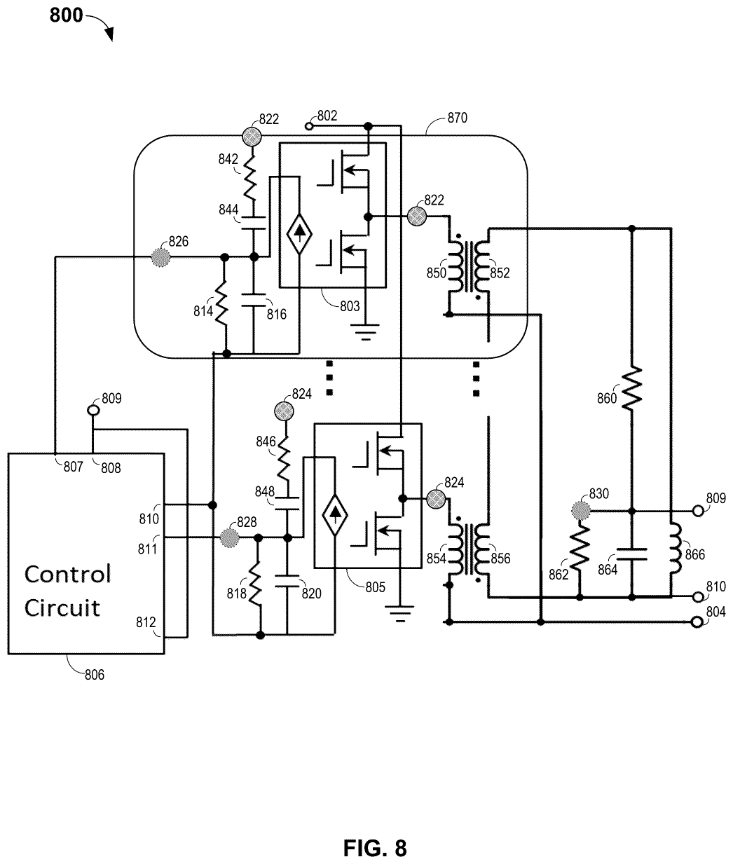

FIG. 8 shows circuit 800 including multiple coupled inductors coupled to TLVR and DrMOS circuitry, in accordance with some embodiments of the present disclosure. In circuit 800, elements 802, 803, 804, 805, 806, 807, 808, 810, 811, 812, 814, 816, 818, 820, 822, 824, 826, 828, 830, 842, 844, 846, 848, 850, 852, 854, 856, 860, 862, 864, and 866 may, in some embodiments, respectively correspond to elements 602, 603, 604, 605, 606, 607, 608, 610, 611, 612, 614, 616, 618, 620, 622, 624, 626, 628, 630, 642, 644, 646, 648, 650, 652, 654, 656, 660, 662, 664, and 666. Compared to circuit 600, circuit 800 includes one less pin (e.g., there is no element corresponding to pin 609) in control circuit block 806. In some embodiments, removal of this pin improves the flexibility of devices that can operate as the control circuit block 806. In the absence of a pin coupling node 830 to control circuit block 806, reference 809 may be coupled to pins 808 and 812.

During operation of circuit 800, current may be sensed through each respective coupled inductor based on the abovementioned procedure for current sensing in circuit 600 (e.g., based on the corresponding elements therein).

Output 804 of circuit 800 may be coupled in series with at least the input windings 850 and 854. In some embodiments, a load may be coupled to output 804.

Circuit 800 may be extended to more than three phases, as indicated by the “ . . . ”, where each additional phase may include a reiteration of the cumulative circuit elements shown in block 870 and the corresponding couplings. Inclusion of such additional phases may also include additional connections to control circuit block 806 (e.g., additional iterations of pins 811 and 812, which respectively correspond to positive and negative connections from an N-phase circuit block to a control circuit).

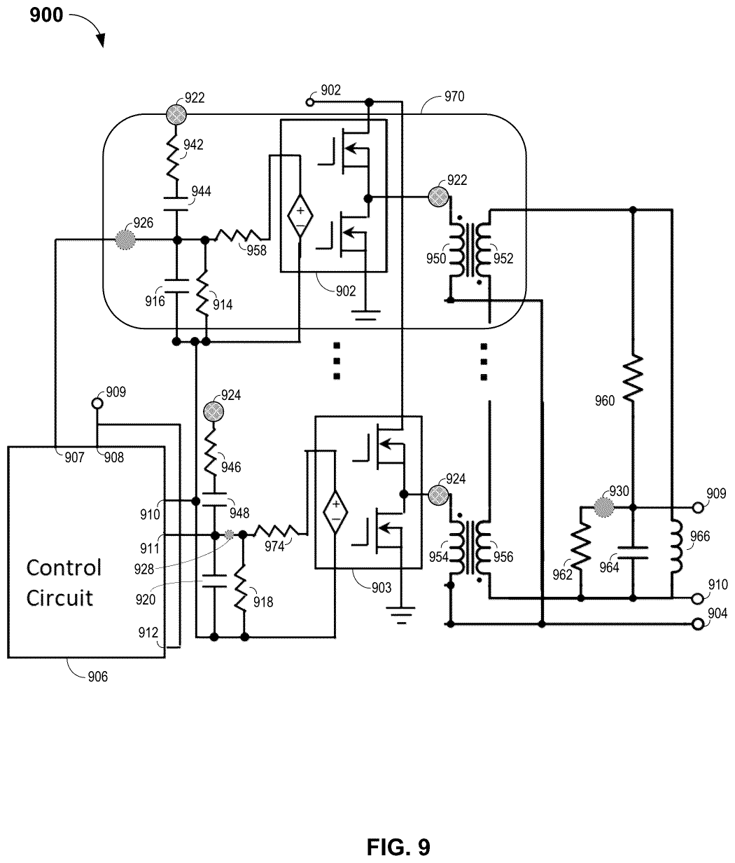

FIG. 9 shows circuit 900 including multiple coupled inductors coupled to TLVR and DrMOS circuitry, in accordance with some embodiments of the present disclosure. In circuit 900, elements 902, 903, 904, 905, 906, 909, 908, 910, 911, 912, 914, 916, 918, 920, 922, 924, 926, 929, 930, 942, 944, 946, 948, 950, 952, 954, 956, 958, 960, 962, 964, 966, and 974 may, in some embodiments, respectively correspond to elements 702, 703, 704, 705, 706, 707, 708, 710, 711, 712, 714, 716, 718, 720, 722, 724, 726, 727, 730, 742, 744, 746, 748, 750, 752, 754, 756, 758, 760, 762, 764, 766, and 774. Compared to circuit 700, circuit 900 includes one less pin (e.g., there is no element corresponding to pin 709) in control circuit block 906. In some embodiments, removal of this pin improves the flexibility of devices that can operate as the control circuit block 906. In the absence of a pin coupling node 930 to control circuit block 906, reference 909 may be coupled to pins 908 and 912.

During operation of circuit 900, current may be sensed through each respective coupled inductor based on the abovementioned procedure for current sensing in circuit 700 (e.g., based on the corresponding elements therein).

Output 904 of circuit 800 may be coupled in series with at least the input windings 950 and 954. In some embodiments, a load may be coupled to output 904.

Circuit 900 may be extended to more than three phases, as indicated by the “ . . . ”, where each additional phase may include a reiteration of the cumulative circuit elements shown in block 970 and the corresponding couplings. Inclusion of such additional phases may also include additional connections to control circuit block 906 (e.g., additional iterations of pins 911 and 912, which respectively correspond to positive and negative connections from an N-phase circuit block to a control circuit).

Thus it has been shown that circuitry for sensing currents flowing through coupled inductors has been provided.

The terms “coupled to”, “coupled with” and variations thereof may indicate that two or more circuit elements are electrically connected to each other (e.g., by a wire, a magnetic core, a common node, or any other suitable connection). For example, windings of a coupled inductor may be coupled via a shared magnetic core (e.g., around which each winding is wound). Devices that are coupled to or with each other need not be directly coupled to or with each other. For example, devices that are coupled to or with each other may be coupled directly or indirectly (e.g., through one or more intermediary elements).

The terms “input” and “output” may be used to characterize portions of a circuit. It will be understood that these characterizations are merely for the purpose of illustrating some embodiments of the present disclosure. An input may serve as an output, and vice versa. Either one of an input or an output may be coupled to additional circuitry that is not shown, including a source or a load, without changing the function of the circuit as shown or the related teachings.

The term “phase” may be used to characterize a mode of operation of a circuit. A phase may correspond to a sequence of time in which a certain current is being driven across a winding. For a given circuit, the number of windings and/or the number of coupled inductors may correspond to the number of phases of the circuit. In some embodiments, a duty cycle of a circuit includes sequential operation through each phase thereof. “Phase” may similarly be used to characterize a temporal offset, including a phase shift, as may be associated with a frequency, duty cycle, or other repetitive operation. For example, respective phase-based modes for operating a circuit may be associated with respective phase shifts.

The term “path” may be used to characterize portions of a circuit, including a sequence of coupled elements. In some embodiments, a path includes at least a wire through which current may conduct. In some embodiments, a path includes one or more devices (e.g., resistors, capacitors, windings, coupled inductors, switches, control circuits, DrMOS blocks, any other suitable device, or any combination thereof).

The term “block” may be used to characterize portions of a circuit, including a sequence of coupled elements. In some embodiments, a block includes a group of circuit elements that may operate in coordination with each other and be lumped together for ease of characterization.

The term “node” may be used to characterize a connected portion of a circuit (e.g., a wire) that shares a single voltage at a given moment of operation.

The term “time constant” may be used to characterize a transient response of a circuit (e.g., how fast the circuit responds to any change in an input, output, or coupling thereto). In some embodiments, the time constant of a given circuit path may be given by the product of a resistance and a capacitance, e.g., as may be present in an RC path, or by the product of an inductance and a reciprocal resistance, e.g., as may be present in an inductor-resistor (RL) path.

The term “toggling” may be used to characterize the act of once or repeatedly turning a switch ON (e.g., creating a closed connection across the switch) and then OFF (e.g., creating an open connection across the switch). Toggling may be associated with a given frequency, which may correspond to the number of times per second that a given switch is turned ON. Toggling may similarly be associated with a duty cycle, which may be equal to the reciprocal of the frequency and may correspond to the amount of time in between successive operations of turning a switch ON. In such operation, the switch may be turned OFF after each time it is turned ON. For example, the switch may be ON for half of a duty cycle (or any other suitable amount of the duty cycle) and may be OFF for the remainder of the duty cycle.

The use of “ . . . ” in a depiction of a circuit may indicate the possible inclusion of one or more repeated circuit elements (e.g., phases of a multi-phase circuit), which may not be explicitly (e.g., for brevity and clarity). It will be understood that representative units of circuitry, as may be shown above or below the “ . . . ”, may be reiterated and coupled to the depicted circuitry in some embodiments of the present disclosure. These reiterated units of circuitry may have inputs, outputs, and elements therein corresponding to a representative unit of circuitry as shown.

The foregoing description of various embodiments has been presented for the purposes of illustration and description. It is not intended to be exhaustive or to be limited to the precise forms disclosed. Many modifications and variations are possible in light of the above teaching.

What is claimed is:

1. A current sensing circuit, comprising:
a coupled inductor comprising:
a first winding, and
a second winding;
a first resistor;
a first capacitor comprising:
a first side coupled in series with the first resistor, wherein the first resistor and the first capacitor are coupled in parallel with the first winding, and
a second side coupled to a second capacitor;
a second resistor;
the second capacitor comprising:
a first side coupled in series with the second resistor, wherein the second resistor and the second capacitor are coupled in parallel with the second winding, and
a second side coupled to the first capacitor; and
a third capacitor comprising:
a first side coupled between the first resistor and the first capacitor, and
a second side coupled between the second resistor and the second capacitor, wherein:
a first voltage across the first capacitor is indicative of a first current flowing through the first winding, and
a second voltage across the second capacitor is indicative of a second current flowing through the second winding.

2. The circuit of claim 1, further comprising a third resistor coupled in series with the third capacitor, wherein the third resistor alters a time constant of the coupled inductor.

3. The circuit of claim 1, further comprising at least one third resistor coupled in parallel with at least one of the first capacitor, the second capacitor, or the third capacitor, wherein the at least one third resistor scales at least one of the first or second voltages.

4. The circuit of claim 1, further comprising a plurality of switches to control current flows through the first and second windings.

5. The circuit of claim 4, wherein:
the plurality of switches comprises first and second switches coupled in series and third and fourth switches coupled in series,
the first winding is coupled between the first and second switches, and
the second winding is coupled between the third and fourth switches.

6. The circuit of claim 1, wherein outputs of the first and second windings are coupled, the circuit further comprising:
a third winding, wherein:
a first side of the third winding is coupled in series with the coupled outputs of the first and second windings, and
a second side of the third winding is coupled between the first and second capacitors.

7. The circuit of claim 1, wherein outputs of the first and second windings are coupled, the circuit further comprising:
N−2 windings, wherein:
N corresponds to a number of phases of the coupled inductor, and
each winding of the N−2 windings corresponds to a respective phase and has an output coupled to the coupled outputs of the first and second windings;
N−2 phase resistors, each corresponding to a respective phase;
N−2 phase capacitors, each corresponding to a respective phase and comprising:
a first side coupled in series with a respective one of the N−2 phase resistors, wherein each respective one of the N−2 phase resistors and one of the N−2 phase capacitors are coupled in parallel with a corresponding one of the N−2 windings, and
a second side coupled to the coupled outputs of the first and second windings; and
(N−1)!−1 coupling capacitors, each one of the (N−1)!−1 coupling capacitors comprising:
a first side coupled between a first respective phase resistor and a corresponding first respective phase capacitor, and
a second side coupled between a second respective phase resistor and a corresponding second respective phase capacitor.

8. A current sensing circuit, comprising:
a coupled inductor comprising N windings, wherein:
N corresponds to a number of phases of the coupled inductor, and
the N windings have coupled outputs;
N first resistors;
N first capacitors, each comprising:
a first side coupled in series with a corresponding first resistor, wherein a respective first resistor and a respective first capacitor are coupled in parallel with a respective one of the N windings, and
a second side coupled to the coupled outputs of the N windings;
N first amplifiers, wherein:
a first input to each first amplifier is coupled between a respective first resistor and a respective first capacitor, and
a second input to each first amplifier is coupled to the coupled outputs of the N windings; and
a second amplifier and N second resistors, wherein:
a first input to the second amplifier is coupled to the coupled outputs of the N windings; and
a second input to the second amplifier is coupled to a common node, wherein:
each input to each respective winding is coupled in series with a respective one of the N second resistors, and each respective one of the N second resistors is further coupled to the common node, and
a respective sum of an output voltage of each respective one of the N first amplifiers and an output voltage of the second amplifier is indicative of a respective current flowing through a respective winding of the N windings.

9. The circuit of claim 8, further comprising N third resistors, wherein:
each one of the N third resistors is coupled in parallel with a respective one of the N first capacitors, and
each one of the N the third resistor scales the first input to the each one of the first amplifiers.

10. The circuit of claim 8, further comprising a plurality of switches to control current flows through the N windings.

11. The circuit of claim 10, wherein:
the plurality of switches comprises N pairs of first and second switches, each of the first and second switches coupled in series, and
each respective winding is coupled between the first and second switches of a respective pair of first and second switches.

12. The circuit of claim 8, further comprising a third capacitor comprising:
a first side coupled to the common node, and
a second side coupled to the coupled outputs of the N windings.

13. A current sensing circuit, comprising:
a first coupled inductor comprising a first input winding and a first output winding;
a second coupled inductor comprising a second input winding and a second output winding, wherein the first output winding is coupled in series with the second output winding;
first and second resistors;
a first capacitor comprising:
a first side coupled in series with the first resistor and in parallel with the second resistor, and
a second side coupled in series with the first input winding;
third and fourth resistors;
a second capacitor comprising:
a first side coupled in series with the third resistor and in parallel with the fourth resistor, and
a second side coupled in series with the second input winding;
a third inductor coupled in series with the first and second output windings;
fifth and sixth resistors, coupled in series; and
a third capacitor comprising:
a first side coupled in between the fifth and sixth resistors, and
a second side coupled in between the second output winding and the third inductor, wherein:
a difference between a first voltage across the first capacitor and a sense voltage across the third capacitor is indicative of a first current flowing through the first coupled inductor, and
a difference between a second voltage across the second capacitor and the sense voltage across the third capacitor is indicative of a second current flowing through the second coupled inductor.

14. The circuit of claim 13, further comprising a plurality of switches to control current flows through the first and second windings.

15. The circuit of claim 14, wherein:
the plurality of switches comprises first and second switches coupled in series and third and fourth switches coupled in series,
the first input winding is coupled between the first and second switches, and
the second input winding is coupled between the third and fourth switches.

16. The circuit of claim 13, further comprising:
N−2 coupled inductors, each comprising a respective input winding and a respective output winding, wherein:
N corresponds to a number of phases of the coupled inductors, and
the respective output windings of the N−2 coupled inductors are coupled in series;
2N−4 resistors, wherein each one of the N−2 coupled inductors is coupled to a corresponding two of the 2N−4 resistors;
N−2 capacitors, wherein each one of the N−2 coupled inductors is coupled to a corresponding one of the N−2 capacitors, each of the N−2 capacitors comprising:
a first side coupled in series with a first resistor of the corresponding two of the 2N−4 resistors and in parallel with a second resistor of the corresponding two of the 2N−4 resistors, and
a second side coupled in series with a corresponding respective input winding of one of the N−2 coupled inductors, wherein:
a current flowing through each one of the N−2 coupled inductors is indicated by a difference between a voltage across a corresponding one of the N−2 capacitors and the sense voltage.

17. A current sensing circuit, comprising:
a first coupled inductor comprising a first input winding and a first output winding;
a second coupled inductor comprising a second input winding and a second output winding, wherein the first output winding is coupled in series with the second output winding;
first and second DrMOS blocks to control current flowing through the first and second coupled inductors, wherein first outputs of the first and second DrMOS blocks are respectively coupled in series with the first and second input windings;
a first capacitor comprising:
a first side coupled in series with a second output of the first DrMOS block, and
a second side coupled with a first reference voltage;
a second capacitor comprising:
a first side coupled in series with a second output of the second DrMOS block, and
a second side coupled with a second reference voltage;
first and second resistors, respectively coupled in parallel with the first and second capacitors;
a third inductor coupled in series with the first and second output windings;
a third resistor and a third capacitor, coupled in series between the first and second outputs of the first DrMOS block;
a fourth resistor and a fourth capacitor, coupled in series between the first and second outputs of the second DrMOS block; and
a fifth capacitor comprising:
a first side coupled in series with a fifth resistor and in parallel with a sixth resistor, and
a second side coupled in between the second output winding and the third inductor, wherein:
a difference between a first voltage across the first capacitor and a voltage across the fifth capacitor is indicative of a first current flowing through the first coupled inductor, and
a difference between a second voltage across the second capacitor and the voltage across the fifth capacitor is indicative of a second current flowing through the second coupled inductor.

18. The circuit of claim 17, further comprising:
control circuitry to control the first and second DrMOS blocks, wherein:
first and second outputs of the control circuitry are respectively coupled to first and second sides of the first capacitor, and
third and fourth outputs of the control circuitry are respectively coupled to first and second sides of the second capacitor.

19. The circuit of claim 17, further comprising:
a fifth resistor coupled in parallel with the first capacitor, wherein the fifth resistor scales the first voltage across the first capacitor; and
a sixth resistor coupled in parallel with the second capacitor, wherein the sixth resistor scales the second voltage across the second capacitor.

20. The circuit of claim 17, further comprising:
N−2 coupled inductors, wherein:
N corresponds to a number of phases of the coupled inductors,
each coupled inductor comprises an input winding and an output winding, and
output windings of the N−2 coupled inductors are coupled in series with the first and second output windings;
N−2 DrMOS blocks, each corresponding to a respective phase and configured to control current flowing through a respective one the N−2 coupled inductors; and
2N−4 resistors and 2N−4 capacitors, wherein:
two resistors of the 2N−4 resistors and two capacitors of the 2N−4 capacitors correspond to each respective phase,
a first of the two resistors of the 2N−4 resistors and a first of the two capacitors of the 2N−4 capacitors are coupled in parallel between a first output of a corresponding DrMOS block and a corresponding reference voltage,
a second of the two resistors of the 2N−4 resistors and a second of the two capacitors of the 2N−4 capacitors are coupled in series between first and second outputs of the corresponding DrMOS block, wherein:
each difference between a voltage across the first of the two capacitors and the voltage across the fifth capacitor is indicative of a respective current flowing through a corresponding coupled inductor.
